(19) United States
(12) Patent Application Publication
(10) Pub. No.: US 2026/0372074 A1
(43) Pub. Date: Nov. 19, 2026

(54) SEMICONDUCTOR PACKAGE AND METHOD OF MANUFACTURING SEMICONDUCTOR PACKAGE

(71) Applicant: Taiwan Semiconductor Manufacturing Company, Ltd., Hsinchu (TW)

(72) Inventors: Ming-Da Cheng, Taoyuan City (TW); Yao-Chun Chuang, Hsinchu City (TW); Chen-Nan Chiu, Hsinchu City (TW); Jui Shen Chang, Taichung City (TW); Yu-Sheng Lin, Hsinchu County (TW); Hsu-Hsien Chen, Hsinchu City (TW)

(73) Assignee: Taiwan Semiconductor Manufacturing Company, Ltd., Hsinchu (TW)

(21) Appl. No.: 19/207,407

(22) Filed: May 14, 2025

(51) Int. Cl. H10W 40/22; H10W 40/25; H10W 70/63; H10W 76/42; H10W 90/00

(52) U.S. Cl. CPC H10W 40/22; H10W 40/25; H10W 70/635; H10W 90/00; H10W 90/701; H10W 76/42; H10W 90/736

(57) ABSTRACT

A semiconductor package includes a substrate, a first die over the substrate, a plurality of peripheral dies over the substrate and surrounding the first die, a thermal interface material and a lid structure. The plurality of peripheral dies include a patterned peripheral die having a groove pattern on a backside surface of the patterned peripheral die. The thermal interface material is disposed on the first die and the plurality of peripheral dies and filling the groove pattern. The lid structure is disposed over the substrate and attached to the first die and the plurality of peripheral dies through the thermal interface material.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 9 illustrate cross-sectional views of intermediate stages in the manufacturing of a semiconductor package according to some embodiments of the present disclosure.

FIG. 10 to FIG. 11 illustrate partial enlarged views of a second semiconductor device and a first semiconductor device of the semiconductor package shown in FIG. 9.

FIG. 12 to FIG. 14 illustrate top views of a second semiconductor device of a semiconductor package according to different embodiments of the present disclosure.

FIG. 15 illustrates a cross-sectional view of intermediate stages in the manufacturing of a semiconductor package according to some embodiments of the present disclosure.

FIG. 16 illustrates a partial enlarged view of the semiconductor package shown in FIG. 15.

FIG. 17 to FIG. 18 illustrate cross-sectional views of intermediate stages in the manufacturing of a semiconductor package according to some embodiments of the present disclosure.

FIG. 19 to FIG. 20 illustrate top views of intermediate stages in the manufacturing of a semiconductor package according to some embodiments of the present disclosure.

FIG. 21 illustrates a partial enlarged and cross-sectional view of a second semiconductor device of a semiconductor package according to some embodiments of the present disclosure.

FIG. 22 to FIG. 23 illustrate top views of intermediate stages in the manufacturing of a semiconductor package according to some embodiments of the present disclosure.

FIG. 24 to FIG. 29 illustrate cross-sectional views of intermediate stages in the manufacturing of a semiconductor package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of the embodiments described herein. Some embodiments described herein are described in the context of 3D IC packages or 2.5D IC packages. Some variations of the exemplary methods and structures are described in the embodiments of the disclosure. A person having ordinary skill in the art will readily understand other modifications may be made that are contemplated within the scope of other embodiments. Although embodiments of the method may be described in a particular order, various other embodiments of the method may be performed in any logical order and may include fewer or more steps than what is described herein.

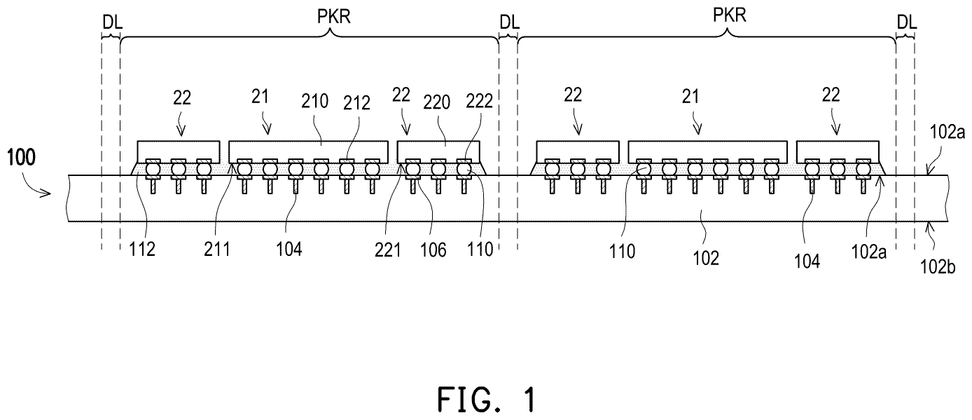

FIG. 1 to FIG. 9 illustrate cross-sectional views of intermediate stages in the manufacturing of a semiconductor package according to some embodiments of the present disclosure. Referring to FIG. 1, an interposer structure 100 is provided. In some embodiments, the interposer structure 100 includes a core portion 102, and a plurality of through vias 104 and conductive pads 106 formed therein. In some embodiments, the core portion 102 is a substrate such as a bulk semiconductor substrate, silicon on insulator (SOI) substrate or a multi-layered semiconductor material substrate. The semiconductor material of the substrate (core portion 102) may be silicon, germanium, silicon germanium, silicon carbide, gallium arsenic, gallium phosphide, indium phosphide, indium arsenide, indium antimonide, GaAsP, AlInAs, AlGaAs, GaInAs, GaInP, GaInAsP, or combinations thereof. In some embodiments, the core portion 102 is doped or undoped.

In some embodiments, the conductive pads 106 are formed on a first surface 102a of the core portion 102. In some embodiments, through vias 104 are formed in the core portion 102 and connected with the conductive pads 106. In some embodiments, the through vias 104 extend into the core portion 102 with a specific depth. In some embodiments, the through vias 104 are through-substrate vias. In some embodiments, the through vias 104 are through-silicon vias when the core portion 102 is a silicon substrate. In some embodiments, the through vias 104 are formed by forming holes or recesses in the core portion 102 and then filling the recesses with a conductive material. In some embodiments, the recesses are formed by, for example, etching, milling, laser drilling or the like. In some embodiments, the conductive material is formed by an electro-chemical plating process, chemical vapor deposition (CVD), atomic layer deposition (ALD) or physical vapor deposition (PVD), and the conductive material may include copper, tungsten, aluminum, silver, gold or a combination thereof. In some embodiments, the conductive pads 106 connected with the through vias 104 are formed as conductive parts of the redistribution layer(s) formed on the interposer structure 100. In some embodiments, the conductive pads 106 include under bump metallurgies (UBMs). In certain embodiments, the interposer structure 100 may further include active or passive devices, such as transistors, capacitors, resistors, or diodes passive devices formed in the core portion 102.

As shown in FIG. 1, the core portion 102 has a plurality of package regions PKR and a dicing lane DL separating each of the plurality of package regions PKR. The through vias 104 and conductive pads 106 are formed in the core portion 102 within the package regions PKR. In some embodiments, a plurality of semiconductor dies 21 (first semiconductor dies) and a plurality of semiconductor dies 22 (second semiconductor dies) are provided on the interposer structure 100, or on the core portion 102 within the package regions PKR in a side by side manner. The first semiconductor dies 21 and the second semiconductor dies 22 are individual dies singulated from a wafer. In some embodiments, the first semiconductor dies 21 contain the same circuitry, such as devices and metallization patterns, or the first semiconductor dies 21 are the same type of dies. In some embodiments, the second semiconductor dies 22 contain the same circuitry, or the second semiconductor dies 22 are the same type of dies. In certain embodiments, the first semiconductor dies 21 and the second semiconductor dies 22 have different circuitry or are different types of dies. In some embodiments, the first semiconductor dies 21 and the second semiconductor dies 22 may have the same circuitry.

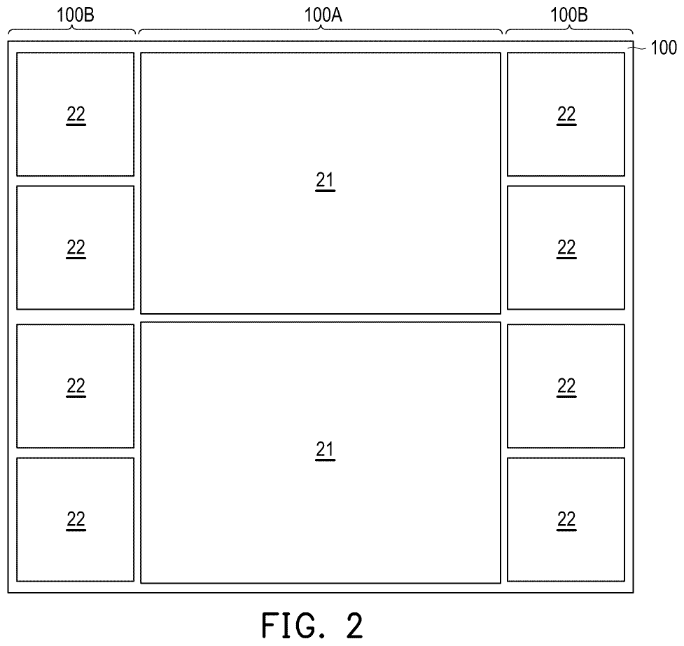

In some embodiments, the first semiconductor dies 21 are major dies (e.g., higher power consuming dies such as logic dies), while the semiconductor dies 22 are tributary dies (e.g., lower power consuming dies such as memory dies). As illustrated in FIG. 2, first semiconductor dies 21 (major dies) are arranged on the core portion 102 in a central region 100A of the interposer structure 100 in each package region PKR, so the first semiconductor dies 21 may also referred to as center dies 21. The second semiconductor dies 22 (tributary dies) are disposed over a peripheral region 100B of the interposer structure 100 surrounding the first semiconductor dies 21, and arranged side-by-side and spaced apart from the first semiconductor dies 21, so the second semiconductor dies 22 may also referred to as peripheral dies 22. In some embodiments, the peripheral dies 22 are arranged aside the center dies 21, and around or surrounding the center dies 21. It is noted that “central” and “peripheral” herein may not be interpreted literally but rather be deemed as spatially relative terms, which are intended to encompass different orientations of the device in use or operation in addition to the orientation depicted in the figures.

Referring back to FIG. 1, in some embodiments, the first semiconductor dies 21 has a surface area larger than that of the second semiconductor dies 22. Also, in some embodiments, the first semiconductor dies 21 and the second semiconductor dies 22 are of different sizes, including different surface areas and/or different thicknesses. In some embodiments, the first semiconductor dies 21 are a logic die, including a central processing unit (CPU) die, graphics processing unit (GPU) die, system-on-a-chip (SoC) die, a microcontroller or the like. In some embodiments, the first semiconductor dies 21 is a power management die, such as a power management integrated circuit (PMIC) die. In some embodiments, the second semiconductor dies 22 are a memory die, including dynamic random access memory (DRAM) die, static random access memory (SRAM) die or a high bandwidth memory (HBM) die. In some embodiments, the second semiconductor dies 22 are dummy dies, which do not perform any electrical functions. The disclosure is not limited thereto, and the number, sizes and types of the semiconductor die disposed on the core portion 102 may be appropriately adjusted based on product requirement.

As illustrated in FIG. 1, the semiconductor dies 21 include a body 210 and connecting pads 212 formed on an active surface 211 of the body 210. In certain embodiments, the connecting pads 212 may further include pillar structures for bonding the semiconductor dies 21 to other structures. In some embodiments, the semiconductor dies 22 include a body 220 and connecting pads 222 formed on an active surface 221 of the body 220. In other embodiments, the connecting pads 222 may further include pillar structures for bonding the dies 22 to other structures.

In some embodiments, the semiconductor dies 21 and the semiconductor dies 22 are attached to the first surface 102a of the core portion 102, for example, through flip-chip bonding by way of the electrical connectors 110. Through a reflow process, the electrical connectors 110 are formed between the connecting pads 212, 222 and conductive pads 106, and are physically connecting the semiconductor dies 21, 22 to the core portion 102 of the interposer structure 100. In some embodiments, the electrical connectors 110 are located in between the semiconductor dies 21, 22 and the interposer structure 100. In certain embodiments, semiconductor dies 21, 22 are electrically connected to the through vias 104 and the conductive pads 106 through the electrical connectors 110. In some embodiments, when the semiconductor dies 22 are dummy dies, the semiconductor dies 22 may be attached to the electrical connectors 110 through physical connection without establishing an electrical connection thereto. In other words, the connecting pads 222 of the semiconductor dies 22 may be dummy pads, for example.

In some embodiments, the semiconductor dies 21 and the semiconductor dies 22 are attached to the first surface 102a of the core portion 102, for example, through flip-chip bonding by way of the electrical connectors 110. Through a reflow process, the electrical connectors 110 are formed between the connecting pads 212, 222 and conductive pads 106, and are physically connecting the semiconductor dies 21, 22 to the core portion 102 of the interposer structure 100. In some embodiments, the electrical connectors 110 are located in between the semiconductor dies 21, 22 and the interposer structure 100. In certain embodiments, semiconductor dies 21, 22 are electrically connected to the through vias 104 and the conductive pads 106 through the electrical connectors 110. In some embodiments, when the semiconductor dies 22 are dummy dies, the semiconductor dies 22 may be attached to the electrical connectors 110 through physical connection without establishing an electrical connection thereto. In other words, the connecting pads 222 of the semiconductor dies 22 may be dummy pads, for example.

In one embodiment, the electrical connectors 110 are micro-bumps, such as micro-bumps having copper metal pillars. In another embodiment, the electrical connectors 110 are solder bumps, lead-free solder bumps, or micro bumps, such as controlled collapse chip connection (C4) bumps or micro bumps containing copper pillars. In some embodiments, the bonding between the semiconductor dies 21, 22 and the core portion 102 is solder bonding. In some embodiments, the bonding between the semiconductor dies 21, 22 and the core portion 102 is direct metal-to-metal bonding, such as copper-to-copper bonding.

Referring to FIG. 1, in some embodiments, an underfill structure 112 may be formed to cover the plurality of electrical connectors 110, and to fill up the spaces in between the semiconductor dies 21, 22 and the interposer structure 100. In some embodiments, the underfill structure 112 further cover side walls of the semiconductor dies 21, 22, and is located within the package region PKR. In some embodiments, an encapsulating material (or molding compound) may be formed over the interposer structure 100 (or over the core portion 102) to cover the underfill structure 112, and to laterally encapsulate the semiconductor dies 21 and 22.

In some embodiments, a material of the insulating encapsulant includes polymers (such as epoxy resins, phenolic resins, silicon-containing resins, or other suitable resins), dielectric materials having low permittivity (Dk) and low loss tangent (Df) properties, or other suitable materials. In another embodiment, the insulating encapsulant may include an acceptable insulating encapsulation material. In some embodiments, the insulating encapsulant may further include inorganic filler or inorganic compound (e.g. silica, clay, and so on) which can be added therein to optimize coefficient of thermal expansion (CTE) of the insulating encapsulant. The disclosure is not limited thereto.

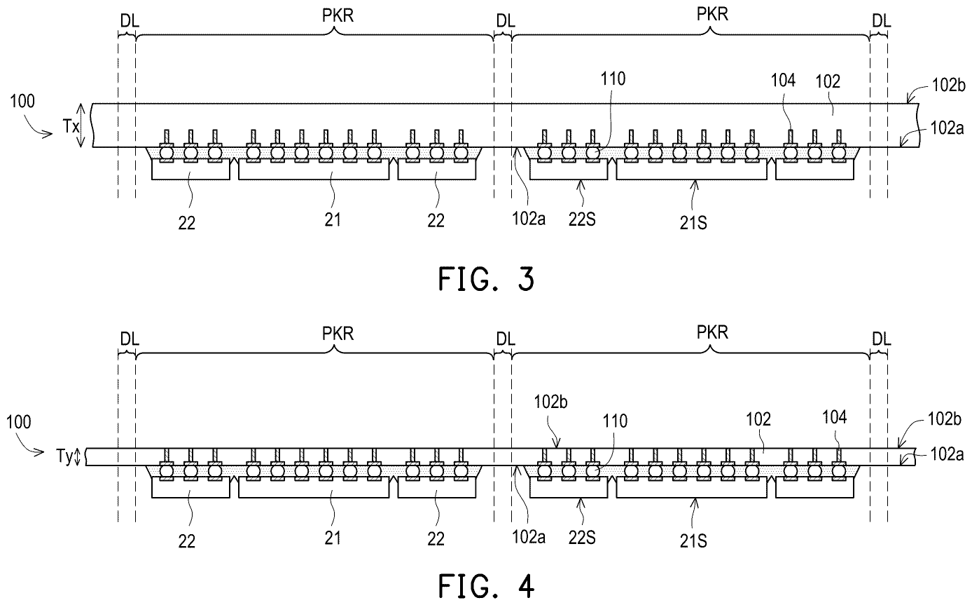

Referring to FIG. 3, the structure of FIG. 1 is turned upside down or flipped, and may be placed on a carrier (not shown), so that the carrier directly contacts the backside surfaces 21S, 22S of the semiconductor dies 21, 22. As shown in FIG. 3, at this stage of processing, the interposer structure 100 has not been thinned and has a thickness Tx. In other words, the through vias 104 are not revealed, and are embedded in the core portion 102 of the interposer structure 100.

Referring to FIG. 4, then, a thinning process is performed to the interposer 100 to partially remove or thin the core portion 102 of the interposer structure 100 until the through vias 104 are exposed and a second surface 102b of the core portion 102 is formed. In some embodiments, the thinning process may include a back-grinding process, a polishing process or an etching process. In some embodiments, after the thinning process, the interposer structure 100 is thinned to a thickness Ty. In some embodiments, a ratio of the thickness Ty to the thickness Tx ranges from about 0.1 to about 0.5.

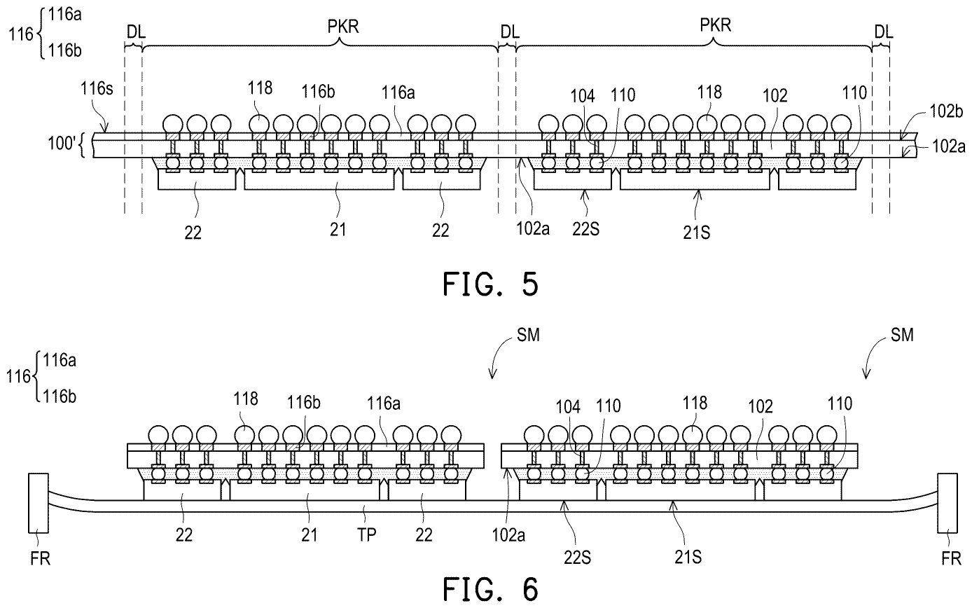

Referring to FIG. 5, a redistribution structure 116 is formed on the second surface 102b of the core portion 102 in the package region PKR and over the dicing lanes DL. The second surface 102b being opposite to the first surface 102a of the core portion 102. In some embodiments, the redistribution structure 116, the core portion 102, the through vias 104 and conductive pads 106 constitutes the interposer structure 100′. In some embodiments, the redistribution structure 116 electrically connects the through vias 104 and/or electrically connects the through vias 104 with external devices. In certain embodiments, the redistribution structure 116 includes at least one dielectric layer 116a and metallization patterns 116b in the dielectric layer 116a. In some embodiments, the metallization patterns 116b may include pads, vias and/or trace lines to interconnect the through vias 104 and to further connect the through vias 104 to one or more external devices. Although one layer of dielectric layer 116a, and one layer of the metallization patterns 116b is shown in FIG. 5, it should be noted that the number of layers of the dielectric layer 116a and the metallization patterns 116b is not limited thereto, and this could be adjusted based on requirement.

In some embodiments, the material of the dielectric layer 116a includes silicon oxide, silicon nitride, silicon carbide, silicon oxynitride, or low-K dielectric materials (such as phosphosilicate glass materials, fluorosilicate glass materials, boro-phosphosilicate glass materials, SiOC, spin-on-glass materials, spin-on-polymers or silicon carbon materials). In some embodiments, the dielectric layer 116a is formed by spin-coating or deposition, including chemical vapor deposition (CVD), PECVD, HDP-CVD, or the like. In some embodiments, the metallization patterns 116b include under-metal metallurgies (UBMs). In some embodiments, the formation of the metallization patterns 116b may include patterning the dielectric layer using photolithography techniques and one or more etching processes and filling a metallic material into the openings of the patterned dielectric layer. Any excessive conductive material on the dielectric layer may be removed, such as by using a chemical mechanical polishing process. In some embodiments, the material of the metallization patterns 116b includes copper, aluminum, tungsten, silver, and combinations thereof.

As further illustrated in FIG. 5, a plurality of conductive terminals 118 is disposed on the metallization patterns 116b, and are electrically coupled to the through vias 104. In some embodiments, the conductive terminals 118 are placed on the top surface 116s of the redistribution structure 116, and electrically connected to the through vias 104 by the metallization patterns 116b within the package region PKR. In certain embodiments, the conductive terminals 118 are positioned on and physically attached to the metallization patterns 116b. In some embodiments, the conductive terminals 118 include lead-free solder balls, solder balls, ball grid array (BGA) balls, bumps, C4 bumps or micro bumps. In some embodiments, the conductive terminals 118 may include a conductive material such as solder, copper, aluminum, gold, nickel, silver, palladium, tin, or a combination thereof. In some embodiments, the conductive terminals 118 are formed by forming the solder paste on the redistribution structure 116 by, for example, evaporation, electroplating, printing or solder transfer and then reflowed into the desired bump shapes. In some embodiments, the conductive terminals 118 are placed on the redistribution structure 116 by ball placement or the like. In other embodiments, the conductive terminals 118 are formed by forming solder-free metal pillars (such as a copper pillar) by sputtering, printing, electroless or electro plating or CVD, and then forming a lead-free cap layer by plating on the metal pillars. The conductive terminals 118 may be used to bond to an external device or an additional electrical component. In some embodiments, the conductive terminals 118 are used to bond to a circuit substrate, a semiconductor substrate or a packaging substrate.

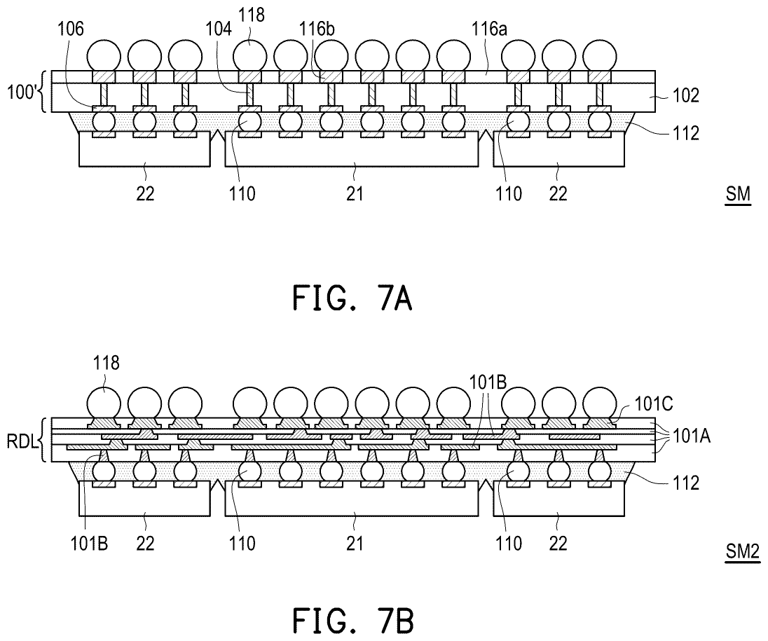

Referring to FIG. 6 and FIG. 7A, in a subsequent step, the structure shown in FIG. 5 is attached to a tape TP (e.g., a dicing tape) supported by a frame FR. Subsequently, the structure shown in FIG. 6 is diced or singulated along the dicing lanes DL to form a plurality of package structures SM. For example, the dicing process is performed to cut through the redistribution structure 116, and the core portion 102 to remove portions of the redistribution structure 116, and the core portion 102 along the dicing lanes DL. In some embodiments, the dicing process or the singulation process typically involves dicing with a rotating blade or a laser beam. In other words, the dicing or singulation process is, for example, a laser cutting process, a mechanical sawing process, or other suitable processes. After the dicing process, the singulated package structure SM illustrated in FIG. 7A can be obtained.

FIG. 7B is a schematic sectional view of a semiconductor package according to some other exemplary embodiments of the present disclosure. The package structure SM2 illustrated in FIG. 7B is similar to the package structure SM illustrated in FIG. 7A. Therefore, the same reference numerals may be used to refer to the same or liked parts, and its detailed description will be omitted herein. The difference between the embodiments is that the interposer structure 100′ with the through vias 104 illustrated in FIG. 7A is replaced with a redistribution layer RDL illustrated in FIG. 7B.

In some embodiments, the redistribution layer RDL is formed by sequentially forming one or more dielectric layers 101A and one or more conductive layers 101B in alternation. In certain embodiments, the conductive layers 101B are sandwiched between the dielectric layers 101A, and are electrically and physically connected to the electrical connectors 110. In the exemplary embodiment, the numbers of the dielectric layers 101A and the conductive layers 101B included in the redistribution layer RDL is not limited thereto, and may be designated and selected based on the design requirements. For example, the numbers of the dielectric layers 101A and the conductive layers 101B may be one or more than one.

In some embodiments, the material of the dielectric layers 101A is polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers DI1 is formed by suitable fabrication techniques such as spin-on coating, chemical vapor deposition (CVD), plasma-enhanced chemical vapor deposition (PECVD) or the like. The disclosure is not limited thereto.

In some embodiments, the material of the conductive layer 101B is made of conductive materials formed by electroplating or deposition, such as aluminum, titanium, copper, nickel, tungsten, and/or alloys thereof, which may be patterned using a photolithography and etching process. In some embodiments, the conductive layer 101B may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In certain embodiments, the redistribution layer RDL further includes a plurality of conductive pads 101C disposed on the conductive layers 101B for electrically connecting with conductive terminals 118. In some embodiments, the materials of the conductive pads 101C may include copper, nickel, titanium, tungsten, or alloys thereof or the like, and may be formed by an electroplating process, for example. The number of conductive pads 101C are not limited in this disclosure, and may be selected based on the design layout. In some embodiments, the conductive pads 101C may be omitted. In other words, the conductive terminals 118 formed in subsequent steps may be directly disposed on the conductive layers 101B of the redistribution layer RDL.

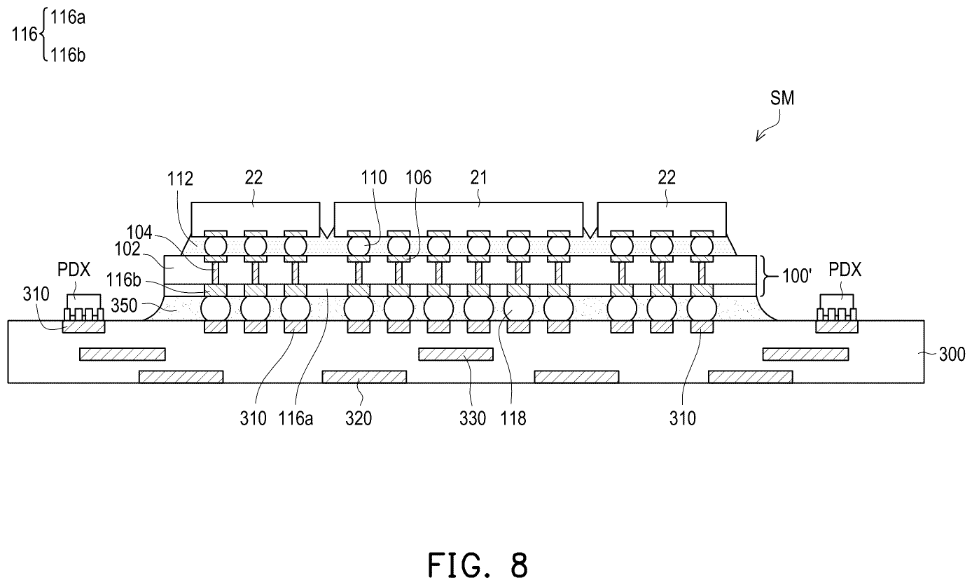

With now reference to FIG. 8, in some embodiments, the package structure SM obtained in FIG. 7A or FIG. 7B (the package structure SM in FIG. 7A is illustrated herein but not limited thereto) is mounted or attached onto a substrate 300 through the conductive terminals 118. In some embodiments, the substrate 300 includes contact pads 310, contact pads 320, metallization layers 330, and vias (not shown). In some embodiments, the contact pads 310 and the contact pads 320 are respectively distributed on two opposite sides of the circuit substrate 300, and are exposed for electrically connecting with later-formed elements/features. In some embodiments, the metallization layers 330 and the vias are embedded in the circuit substrate 300 and together provide routing function for the circuit substrate 300, wherein the metallization layers 330 and the vias are electrically connected to the contact pads 310 and the contact pads 320. In other words, at least some of the contact pads 310 are electrically connected to some of the contact pads 320 through the metallization layers 330 and the vias. In some embodiments, the contact pads 310 and the contact pads 320 may include metal pads or metal alloy pads. In some embodiments, the materials of the metallization layers 330 and the vias may be substantially the same or similar to the material of the contact pads 310 and the contact pads 320.

Furthermore, in some embodiments, the package structure SM is bonded to the circuit substrate 300 through physically connecting the conductive terminals 118 and the contact pads 310 to form a stacked structure. In certain embodiments, the package structure SM is electrically connected to the circuit substrate 300. In some embodiments, the circuit substrate 300 may be an organic flexible substrate or a printed circuit board. In such embodiments, the conductive terminals 118 are, for example, chip connectors. In some embodiments, the package structure SM is bonded to the circuit substrate 300 through physically connecting the conductive terminals 118 and the contact pads 310 of the circuit substrate 300 by, for example, a chip on wafer on substrate (CoWoS®) packaging processes.

In an embodiment, the package structure SM may be connected to the contact pads 310, for example, by sequentially dipping the conductive terminals 118 on the package structure SM into flux, and then using a pick-and-place tool in order to physically align the conductive terminals 118 of the package structure SM with the contact pads 310. In an embodiment in which the package structure SM uses conductive terminals 118 such as solder balls, once the package structure SM has been placed a reflow process may be performed in order to physically bond the package structure SM with the underlying contact pads 310 and a flux clean may be performed. However, any other suitable connector or connection process may be utilized, such as metal-to-metal bonding, dielectric-to dielectric bonding, or the like. In some embodiments, a plasma cleaning process may be performed after the flux cleaning process in order to ensure that the excessive flux is clean for subsequent processes. In some embodiments, the plasma cleaning process is not performed.

In addition, as illustrated in FIG. 8, passive devices PDX (integrated passive device or surface mount devices) may be mounted on the circuit substrate 300. For example, the passive devices PDX may be mounted on the contact pads 310 of the circuit substrate 300 through a soldering process. The disclosure is not limited thereto. In certain embodiments, the passive devices PDX may be mounted on the circuit substrate surrounding the package structure SM. In some embodiments, the passive devices PDX are omitted.

As further illustrated in FIG. 8, in some embodiments, an underfill structure 350 is formed to fill up the spaces in between the circuit substrate 300 and the package structure SM. In certain embodiments, the underfill structure 350 fills up the spaces in between adjacent conductive terminals 118 and covers the conductive terminals 118. For example, the underfill structure 350 surrounds the plurality of conductive terminals 118. In some embodiments, the passive devices PDX is exposed by the underfill structure 350, and kept a distance apart from the underfill structure 350. In other words, the underfill structure 350 does not cover the passive devices PDX.

For thermal management, packaging solutions usually adopt thermal interface material (e.g., the thermal interface material 23) to thermally couple the semiconductor devices (e.g., the semiconductor devices 21, 22) to a lid structure (e.g., the lid structure 500) for heat dissipation. However, thermal interface materials suffers degradation and shrinkage around die edges during thermal process such as high temperature annealing, temperature cycling, etc. This produces stresses and adhesion loss that can cause TIM delamination around the die edges, increasing the overall thermal resistance from die junction to lid structure.

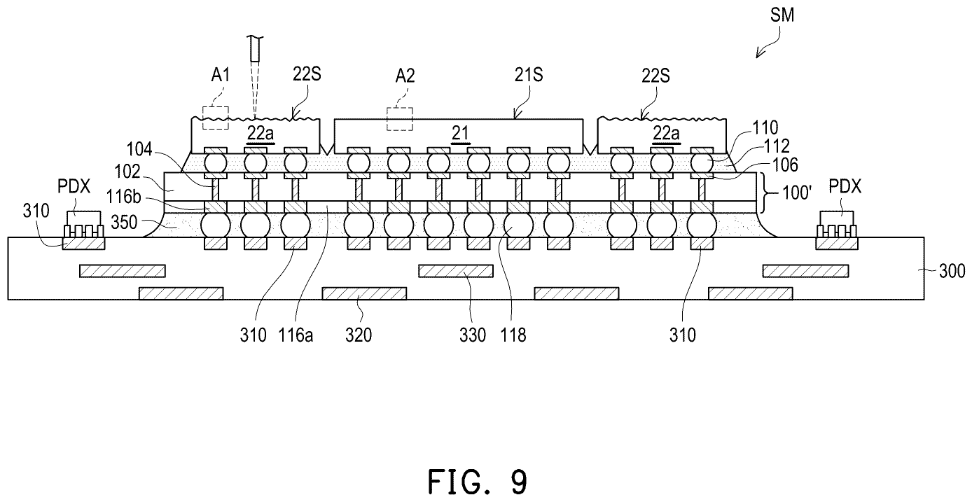

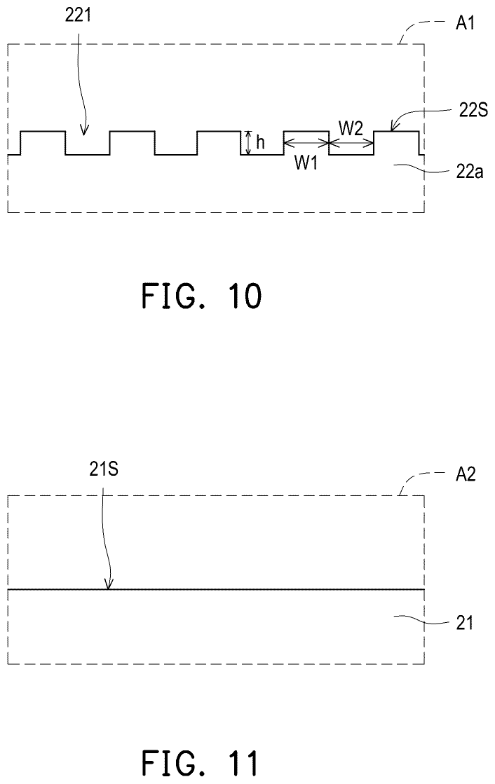

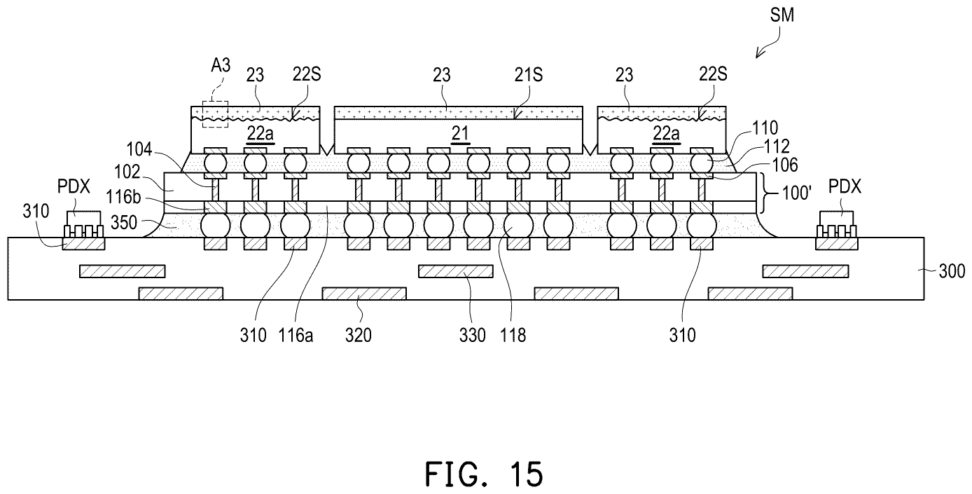

FIG. 10 to FIG. 11 illustrate partial enlarged views of the region A1 of the second semiconductor device 22a and the region A2 of the first semiconductor device 21 of the semiconductor package shown in FIG. 9. Accordingly, referring to FIG. 9 to FIG. 11, in some embodiments, a surface treatment process is performed over the backside of at least one of the second semiconductor devices 22 to form the processed backside surface 22S on the processed second semiconductor devices 22a. After the surface treatment process, a surface roughness of the treated backside surface 22S of the (treated) second semiconductor devices 22a, as it is shown in FIG. 10, is greater than a surface roughness of a backside surface 21S of the (untreated) first semiconductor device 21, as it is shown in FIG. 11, so as to improve the adhesion strength between the second semiconductor devices 22a and a thermal interface material (e.g., the thermal interface material 23 shown in FIG. 15) to be applied thereon subsequently. In other words, a first step height between a highest point and a lowest point of a backside surface 21S of the first semiconductor device 21 is smaller than a second step height h between a highest point and a lowest point of the treated backside surface 22S of the second semiconductor devices 22a.

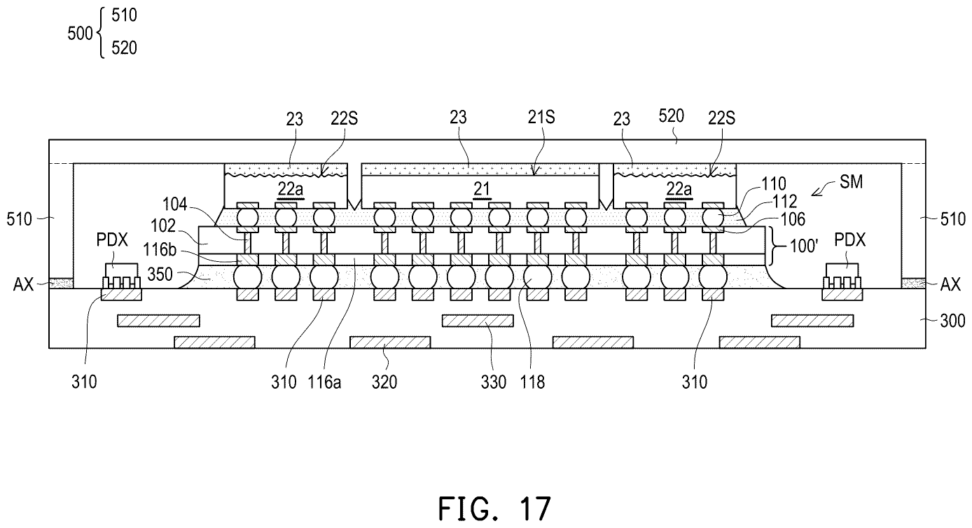

In accordance with some embodiments of the disclosure, the surface treatment process includes a patterning process to form a plurality of grooves 221 by, for example, laser grooving, laser etching, or the like, for roughening the backside surfaces 22S of the second semiconductor devices 22a. In other embodiments, the patterning process may also include surface bombardment process such as sputter etching or ion milling, or other suitable process. As such, the treated second semiconductor devices (patterned peripheral dies) 22a each has a groove pattern on its backside surface 22S, and the treated (e.g., patterned) backside surface 22S may have a regular or irregular surface with peaks and valleys and sharp edges. In some embodiments, the treated backside surface 22S includes one or more grooves 221, which are recessed with respect to the primary backside surfaces of the semiconductor devices 22a. The backside surfaces 22S are the upper surfaces of the semiconductor devices 22a when oriented in a flip-chip configuration as shown in FIG. 9. The grooves 221 may also be referred to by any of various other suitable names, such as trenches, indentations, receptacles, or cavities. The grooves 221 formed over the backside surfaces 22S of the semiconductor devices 22a provide receptacles for accepting a portion of a thermal interface material (e.g., the thermal interface material 23 shown in FIG. 17) that may be forced out when the lid structure (e.g., the lid structure 500 shown in FIG. 17) is positioned on the thermal interface material above the semiconductor devices 21 and 22a during manufacturing.

As an example, a width W2 of each of the grooves 221 may be smaller than or equal to about 10 nm and greater than or equal to about 0.1 nm; a gap W1 between any adjacent two of the grooves 221 may be smaller than or equal to about 10 nm and greater than or equal to about 0.1 nm; and a depth h of each of the grooves 221 may be greater than or equal to about 10 μm, and smaller than or equal to a thickness of the thermal interface material (e.g., the thermal interface material 23 shown in FIG. 15). The term “about” can be used to include any numerical value that can vary without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

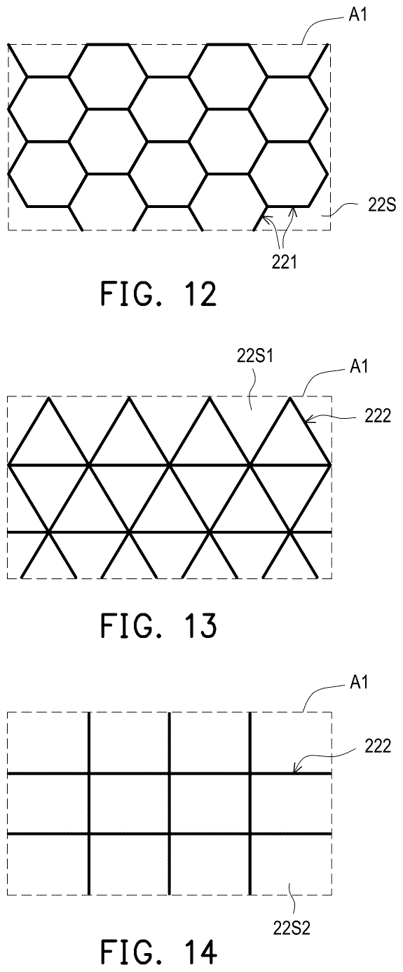

FIG. 12 to FIG. 14 illustrates top views of a second semiconductor device (e.g., a region A1 as shown in FIG. 9) of a semiconductor package according to different embodiments of the present disclosure. In accordance with some embodiments of the disclosure, the grooves 221 form a groove pattern such as a honeycomb pattern as shown in FIG. 12, a triangle array as shown in FIG. 13, a grid array as shown in FIG. 14, or any suitable patterns, over the backside surface 22S of the second semiconductor device 22a.

A common unit of measurement of surface roughness is by measuring the “average surface roughness”, which is often communicated as “Ra” and is the calculated average between peaks and valleys on a surface (e.g., the treated (patterned) backside surface 22S). Accordingly, the characteristics such as patterns, widths, gaps, depths, etc., of the grooves 221 are elaborately controlled so that an average surface roughness (Ra) of the backside surface 22S of the second semiconductor devices 22a is controlled to be within a desirable range. For example, the average surface roughness (Ra) of the backside surface 22S is smaller than or equal to about 3 and greater than or equal to about 1. If the backside surface 22S is treated to be too rough (e.g., Ra>3), the thermal resistance between the second semiconductor device 22a and the thermal interface material may be increased to an undesirable degree. If the backside surface 22S is not treated to be rough enough (e.g., Ra<1), risk of delamination between the second semiconductor device 22a and the thermal interface material may still occur.

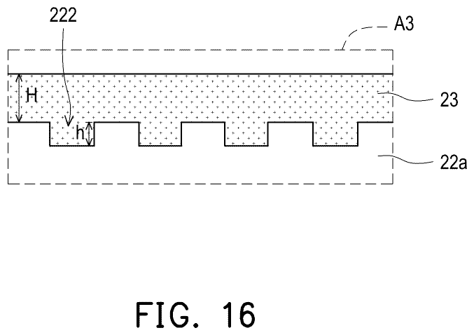

FIG. 15 illustrates a cross-sectional view of intermediate stages in the manufacturing of a semiconductor package according to some embodiments of the present disclosure. FIG. 16 illustrates a partial enlarged view of a region A3 of the semiconductor package shown in FIG. 15. Referring to FIG. 15 and FIG. 16, in some embodiments, a thermal interface material 23 is then provided over the first semiconductor device 21, and the second semiconductor devices 22a. In some embodiments, the thermal interface material 23 may be a polymer having a good thermal conductivity (Tk), which may be between about 3 watts per meter kelvin (W/mK) to about 5 W/mK. In some embodiments, the thermal interface material 23 may include a polymer with thermal conductive fillers. The thermal conductive fillers may increase the effective Tk of the thermal interface material 23 to be between about 10 W/mK to about 50 W/mK or more. Applicable thermal conductive filler materials may include aluminum oxide, boron nitride, aluminum nitride, aluminum, copper, silver, indium, a combination thereof, or the like. In other embodiments, the thermal interface material 23 may include other materials such as a metallic-based or solder-based material comprising silver, indium paste, or the like. Other examples of materials suitable for use as the thermal interface material 23 include thermal grease, thermally conductive epoxy, phase-change materials (PCMs), conductive tapes, and silicone-coated fabrics among other suitable materials.

In some embodiments of the disclosure, the thermal interface material 23 fills the grooves 221 on the backside surface 22S of the second semiconductor devices 22a. A (minimum) thickness H of the thermal interface material 23 is greater than a depth h of each of the grooves 221 (i.e., a step height between a highest point and a lowest point of the backside surface 22S), which is greater than or equal to about 10 μm. In some embodiments, the average surface roughness (Ra) of the backside surface 22S of the second semiconductor devices 22a is greater than or equal to about one-tenth of the thickness H of the thermal interface material 23, and smaller than about half of the thickness H of the thermal interface material 23 (i.e., H/2>Ra≥H/10).

The grooves 221 formed on the backside surface 22S of the second semiconductor devices 22a are intended to receive a portion of the thermal interface material 23. Accordingly, a thickness of the thermal interface material 23 is thicker in these areas where the grooves 221 are located. Thus, the grooves 221 provide anchoring points to enhance adhesion of the thermal interface material 23 to the backside surface 22S of the second semiconductor devices 22a. In this manner, compared to the second semiconductor devices 22a without the groove pattern, the bond line thickness (BLT), i.e., the thickness H of the thermal interface material 23, between the lid structure (e.g., the lid structure 500 in FIG. 17) and the package structure SM may be reduced for decreased thermal resistance while sufficient interfacial adhesion is still provided around peripheral regions of the package structure SM in an effort to avoid delamination of the thermal interface material 23.

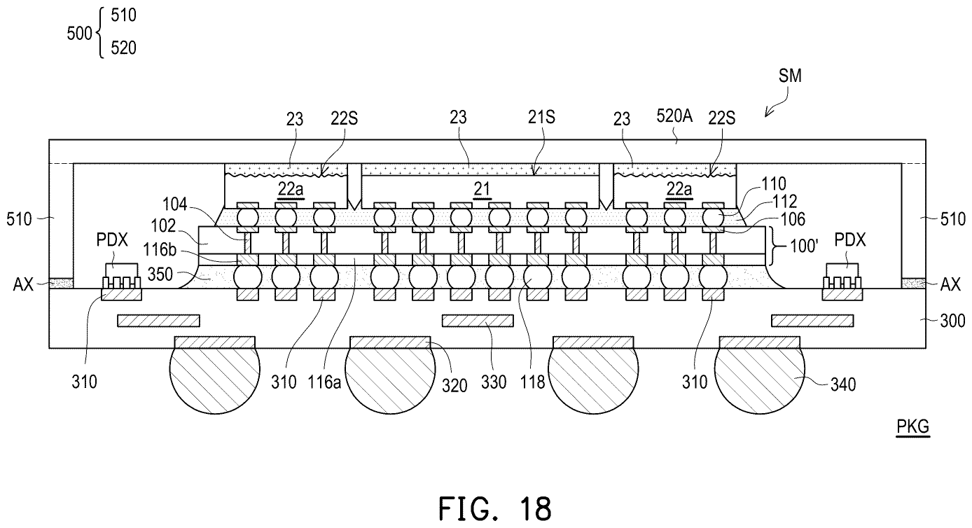

FIG. 17 to FIG. 18 illustrate cross-sectional views of intermediate stages in the manufacturing of a semiconductor package according to some embodiments of the present disclosure. Referring to FIG. 17, in a subsequent step, a lid structure 500 is disposed on the substrate 300. In some embodiments, the lid structure 500 is attached to the substrate 300 through an adhesive material AX. In some embodiments, the lid structure 500 includes a sidewall part 510 and a supporting part 520. For example, the sidewall part 510 is disposed on and attached to the substrate 300 through the adhesive material AX, and is surrounding the semiconductor package SM. Furthermore, the supporting part 520 is disposed on and in physical contact with the sidewall part 510. The supporting part 520 is in physical contact with the thermal interface material 23, and overlapped with the package structure SM and the passive devices PDX. The lid structure 500 covers the package structure SM and is thermally coupled to the first semiconductor device 21 and the second semiconductor devices 22a through the thermal interface material 23.

In some examples, the lid structure 500 may be fabricated from a plastic material or other suitable material. In other examples, particularly where it is desirable to utilize the lid structure 500 to receive and convey heat away from the package structure SM, the lid structure 500 may be fabricated from a thermally conductive material, such as copper, nickel-plated copper, or aluminum, among other suitable materials. The lid structure 500 may have a thickness of between about 0.5 mm and about 3.0 mm, although other thicknesses may be utilized. The thermal interface material 23 may be utilized to thermally and/or mechanically couple the lid structure 500 to the package structure SM. The thermal interface material 23 may be applied between two surfaces, either metal-to-metal or metal-to-semiconductor (e.g., silicon). The thermal interface material 23 provides a thermally conductive path between the to the lid structure 500 to the package structure SM so that heat generated by the semiconductor devices 21, 22a may be dissipated through the lid structure 500. In some embodiments, the thermal interface material 23 may also be a soft or compliant adhesive to allow compensation between mismatched heights of neighboring semiconductor devices 21, 22a within the package structure SM.

In some embodiments, the lid structure 500 has a top surface and a bottom surface opposite to each other. For some examples, the top surface of the lid structure 500 forms the exterior top surface of the semiconductor package, and the bottom surface of the lid structure 500 faces the semiconductor devices 21, 22a. A heat sink (not shown in FIG. 17) may optionally be mounted to the top surface of the lid structure 500.

Referring to FIG. 18, in some embodiments, then, a plurality of conductive bumps 340 are respectively formed on the substrate 300. As illustrated in FIG. 18, for example, the conductive bumps 340 are connected to the contact pads 320 of the substrate 300. In other words, the conductive bumps 340 are electrically connected to the substrate 300 through the contact pads 320. Through the contact pads 310 and the contact pads 320, some of the conductive bumps 340 are electrically connected to the package structure SM (e.g. the semiconductor dies 21 and 22a included therein). In some embodiments, the conductive bumps 340 are, for example, solder balls or BGA balls. At this stage, a semiconductor package PKG shown in FIG. 18 may be substantially formed.

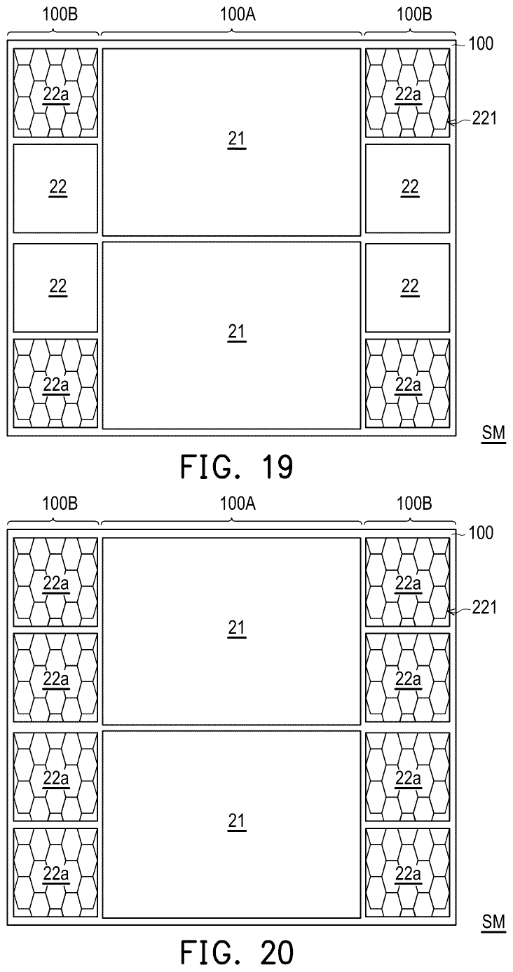

FIG. 19 to FIG. 20 illustrate top views of intermediate stages in the manufacturing of a semiconductor package according to some embodiments of the present disclosure. Referring to FIG. 9 and FIG. 19, in some embodiments, the surface treatment process is performed on at least one corner dies 22a of the second semiconductor devices. That is, the second semiconductor devices 22 surrounding the first semiconductor devices 21, as illustrated in FIG. 2, includes a plurality of the corner dies at a plurality of corners of the package structure SM, for example, four corner dies at four corners of the package structure SM. In the embodiment of FIG. 19, the surface treatment process is performed over the corner dies of the second semiconductor devices 22, but not on the rest of the second semiconductor devices 22. That is, in this embodiment, the second semiconductor devices 22a and 22 are arranged along two opposite sides of the first semiconductor devices 21, wherein the treated (patterned) semiconductor devices 22a with the grooves 221 on their backside surfaces are located at the corners of the package structure SM while the untreated semiconductor devices 22 with substantially flat backside surfaces are located in between. Accordingly, the bonding strength between the thermal interface material 23 and the second semiconductor devices 22a around the corners of the package structure SM can be improved, so as to avoid or at least reduce risk of delamination of the thermal interface material 23 around corner regions of the package structure SM and the heat dissipation of the package structure SM can be improved.

Referring to FIG. 9 and FIG. 20, in the embodiment of FIG. 20, the patterning process is performed over all of the second semiconductor devices. That is, in this embodiment, the treated (patterned) second semiconductor devices 22a with the grooves 221 on their backside surfaces are arranged along two opposite sides of the first semiconductor devices 21. Accordingly, the bonding strength between the thermal interface material 23 and the second semiconductor devices 22a on two opposite sides of the first semiconductor devices 21 can be improved, so as to avoid or at least reduce risk of delamination of the thermal interface material 23 around peripheral region 100B of the package structure SM and the heat dissipation of the package structure SM can be improved.

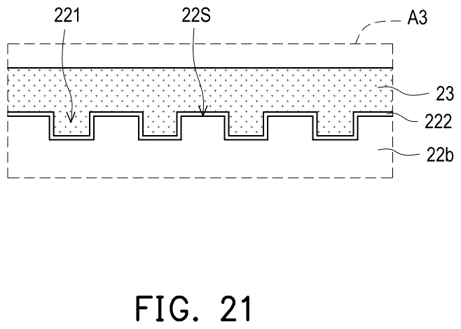

FIG. 21 illustrates a partial enlarged region (e.g., the region A3 shown in FIG. 15) of a second semiconductor device of a semiconductor package according to some embodiments of the present disclosure. It is noted that the semiconductor package shown in FIG. 21 contains many features same as or similar to the semiconductor package disclosed earlier in the previous embodiments. For purpose of clarity and simplicity, detail description of same or similar features may be omitted, and the same or similar reference numbers denote the same or like components. In some embodiments, surface treatment process further includes an adhesion promoting process performed after the patterning process. That is, after the patterning process is performed to form the grooves 221 over the backside surface 22S of the second semiconductor devices 22a as it is shown in FIG. 9, an adhesion promoting process is performed to form adhesion promoting layer 222 over at least one of the patterned second semiconductor devices 22a and form the second semiconductor devices 22b shown in FIG. 21. The adhesion promoting layer 222 is formed to cover the backside surface 22S of the patterned second semiconductor devices 22b in a conformal manner by, for example, deposition process, spin coating process, or the like. In such embodiment, the thermal interface material 23 covers the adhesion promoting layer 222 and fills the valleys of the adhesion promoting layer 222 caused by the grooves 221 underneath.

In some embodiments, the adhesion promoting layer 222 may include silane coupling agents, which contains at least two different reactive groups within their molecules. One of these functional groups forms chemical bonds with inorganic materials (e.g., inorganic materials of the substrate of the semiconductor devices), and the other forms chemical bonds with organic materials (e.g., organic materials in the thermal interface material 23). This property enables silane coupling agents to function as intermediaries in bonding organic materials to inorganic materials, which normally tend not to bond with each other. In one embodiment, the adhesion promoting layer 222 include a silane compound with at least one reactive substituent such as a carboxyl group, a methacryloyl group, an isocyanate group and/or an epoxy group. Specific examples of the adhesion components include trimethoxysilyl benzoic acid, γ-methacryloxypropyl trimethoxy silane, vinyltriacetoxysilane, vinyltrimethoxysilane, γ-isocyanatepropyl triethoxy silane, γ-glycidoxypropyl trimethoxy silane, β-(3,4-epoxycyclohexyl) ethyl trimethoxy silane, benzimidazoles and polybenzimidazoles, a lower hydroxyalkyl substituted pyridine derivative, a nitrogen heterocyclic compound, urea, thiourea, an organophosphorus compound, 8-oxyquinoline, 4-hydroxypteridine and derivatives, 1,10-phenanthroline and derivatives, 2,2′-bipyridine and derivatives, benzotriazoles; organophosphorus compounds, phenylenediamine compounds, 2-amino-1-phenylethanol, N-phenylethanolamine, N-ethyldiethanolamine, N-ethylethanolamine and derivatives, benzothiazole, and a benzothiazoleamine salt having a cyclohexyl ring and a morpholine ring, 3-glycidoxypropyl trimethoxysilane, 3-glycidoxypropyl triethoxysilane, 3-mercaptopropyl trimethoxysilane, 3-mercaptopropyl triethoxysilane, 3-methacryloyloxypropyl trimethoxysilane, vinyl trimethoxysilane, combinations of these, or the like. The detectable elements in the adhesion promoting layer 222 may include nitrogen (N), carbon (C), oxygen (O), sulfur(S), phosphorus (P), chlorine (Cl), fluorine (F), or other detectable elements in any suitable adhesion promoters. The adhesion promoting layer 222 covers side surfaces of the grooves 221 in a conformal manner to further promote adhesion between the thermal interface material 23 and the second semiconductor devices 22b.

In some embodiments, the adhesion promoting process includes performing a plasma treatment over a backside surface of the second semiconductor devices 22a to promote the adhesion between the thermal interface material 23 and the second semiconductor devices 22a. The backside surface of the second semiconductor devices 22a is treated to improve the bonding by a dry treatment such as a plasma treatment. In some embodiments. In one embodiment, a bonding layer (e.g., adhesion promoting layer 222), which is a dielectric layer, may be formed over the backside surface of the second semiconductor devices 22a. The bonding layer may include a silicon-containing dielectric, such as silicon oxide, silicon oxynitride or silane oxide. Then, the surface of the bonding layer is treated to improve the bonding by plasma treatment. In some embodiments, the plasma treatment is performed in an inert environment, such as an environment filled with inert gas including O₂, N₂, Ar, He, or combinations thereof. Alternatively, other types of treatments may be used. In some embodiments, the bonding layer includes silicon oxide, and the plasma process is performed to the bonding layer to form Si—OH bonds on the surface of bonding layer prior to bonding.

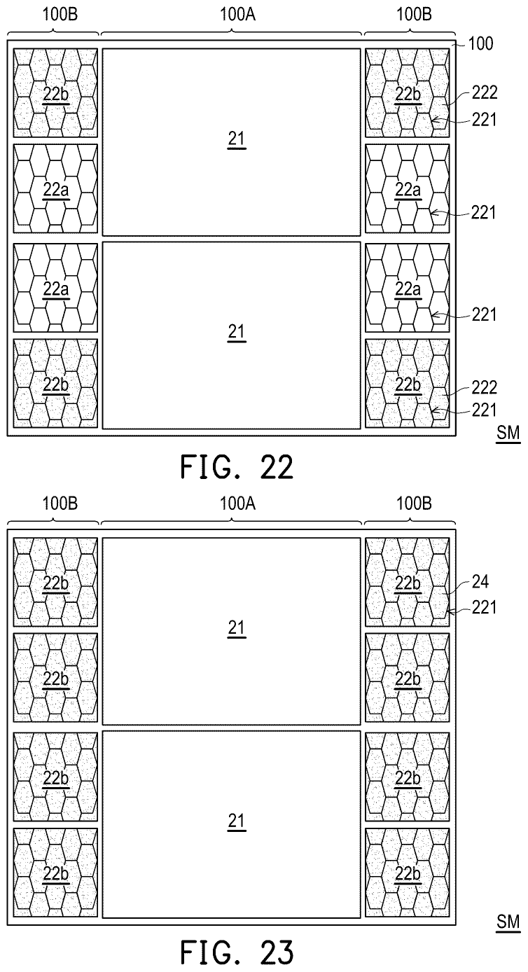

FIG. 22 to FIG. 23 illustrate top views of intermediate stages in the manufacturing of a semiconductor package according to some embodiments of the present disclosure. Referring firstly to FIG. 21 and FIG. 22, in the present embodiment, the patterning process is performed over all of the (peripheral) semiconductor devices. That is, in this embodiment, the treated (patterned) semiconductor devices 22a with the grooves 221 are arranged along two opposite sides of the first semiconductor devices 21. Then, the adhesion promoting layer 222 may cover a first portion of the treated semiconductor devices 22a with the grooves 221, and not cover the rest of the treated semiconductor devices 22a. That is, the adhesion promoting layer 222 covers the first portion of the treated semiconductor devices 22a to form the semiconductor devices 22b as it is shown in FIG. 21, and leaves the second portion of the treated semiconductor devices 22a uncovered, so that the grooves 221 are in direct contact with the thermal interface material 23 as it is shown in FIG. 16. In a structural point of view, the peripheral dies (i.e., second semiconductor devices) arranged along two opposite sides of the first semiconductor devices 21 are treated to include at least one first treated (patterned) peripheral die 22b having the adhesion promoting layer 222 covering a backside surface of the first treated peripheral die 22b in a conformal manner as it is shown in FIG. 21 and a second treated (patterned) peripheral die 22a with the grooves 221 and free of the adhesion promoting layer 222 as it is shown in FIG. 16.

In the embodiment of FIG. 22, the adhesion promoting process is performed at the corner dies of the semiconductor devices 22a to form the semiconductor devices 22b (i.e., corner dies 22b) with the adhesion promoting layer 222 covering the grooves 221 in a conformal manner. That is, the adhesion promoting layer 222 covers the backside surface of the corner dies 22b with the grooves 221, and does not cover the rest of the semiconductor devices 22a. As such, an average surface roughness (Ra) of the backside surface of the corner die 22b with the adhesion promoting layer 222 covering the grooves 221 is greater than the average surface roughness (Ra) of the backside surfaces of the rest of the semiconductor devices 22a without the adhesion promoting layer 222. In other words, a step height of the backside surface of the corner die 22b with the adhesion promoting layer 222 covering the grooves 221 is greater than the step height of the backside surfaces of the rest of the semiconductor devices 22a without the adhesion promoting layer 222. Accordingly, the bonding strength between the thermal interface material 23 and the second semiconductor devices 22a with the grooves 221 on two opposite sides of the first semiconductor devices 21 can be improved, and the corners dies 22b with the adhesion promoting layer 222 covering the grooves 221 in a conformal manner can further enhance the adhesion of the thermal interface material 23 to the corner dies 22a. As such, risk of delamination of the thermal interface material 23 around peripheral region 100B, especially around the corners of the package structure SM can be further reduced, and the heat dissipation of the package structure SM can be improved.

In accordance with some embodiments of the disclosure, the peripheral dies (e.g., the semiconductor devices 22 in FIG. 2) surrounding the center dies (e.g., the semiconductor devices 21 in FIG. 2) may be treated to include at least one first treated peripheral die 22b having a plurality of grooves 221 on the backside surface of the first treated peripheral die 22b, and an adhesion promoting layer 222 covering the backside surface with the grooves 221 in a conformal manner as it is shown in FIG. 21 and a second treated peripheral die 22a with the grooves 221 and free of the adhesion promoting layer 222 as it is shown in FIG. 16. For example, a ratio of a surface area of the backside surface of the first treated peripheral dies 22b to a (total) surface area of the backside surfaces of all the dies (e.g., the center dies and the peripheral dies) is greater than or equal to about 20% and smaller than or equal to about 50%. A ratio of a surface area of the backside surface of the second treated peripheral dies 22a to the total surface area of backside surfaces of all the dies (e.g., the center dies and the peripheral dies) is greater than or equal to about 5% and smaller than or equal to about 20%. The configurations described above are merely for illustration. The surface treatment process (including the patterning process for forming the grooves 221 and/or the adhesion promoting process for forming the adhesion promoting layer 222) can be performed to any part of the semiconductor devices in the package structure SM to form any configuration of the first treated peripheral die 22b and the second treated peripheral die 22a according to actual needs.

With now reference to FIG. 21 and FIG. 23, in the present embodiment, the patterning process is performed over all of the peripheral semiconductor devices arranged along two opposite sides of the semiconductor devices 21 to form a plurality of grooves 221 on the backside surfaces of peripheral semiconductor devices. Then, the adhesion promoting process is performed on such patterned semiconductor devices to form a plurality of semiconductor devices 22b with the adhesion promoting layer 222 covering the grooves 221 in a conformal manner as it is shown in FIG. 21. In a structural point of view, the package structure SM includes a plurality of semiconductor devices 22b arranged along two opposite sides of the first semiconductor devices 21, and a backside surface of each of the semiconductor devices 22b includes a plurality of grooves 221 and an adhesion promoting layer 222 covering the backside surface with the grooves 221 in a conformal manner. Accordingly, the bonding strength between the thermal interface material 23 and the peripheral semiconductor devices 22b surrounding the first semiconductor devices 21 can be further enhanced by the adhesion promoting layer 222 covering the grooves 221 in a conformal manner. As such, risk of delamination of the thermal interface material 23 around peripheral region 100B of the package structure SM can be further reduced, and the heat dissipation of the package structure SM can be improved.

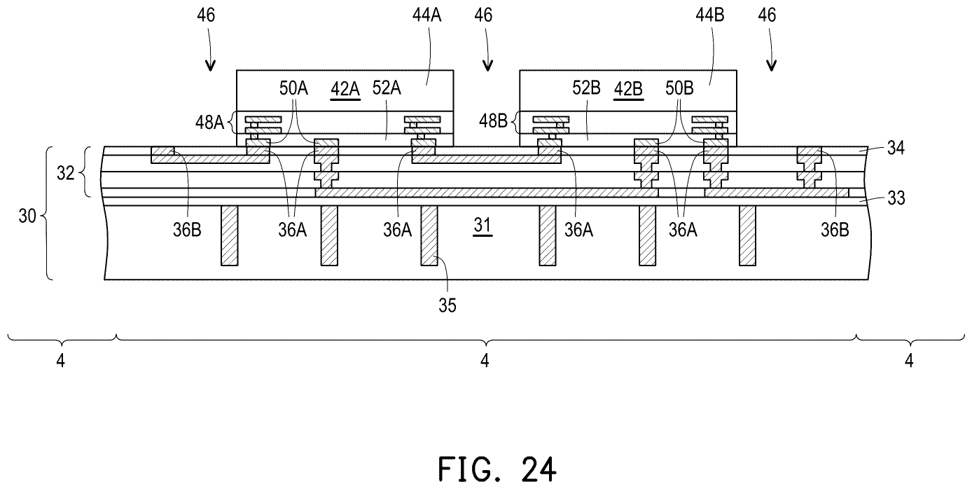

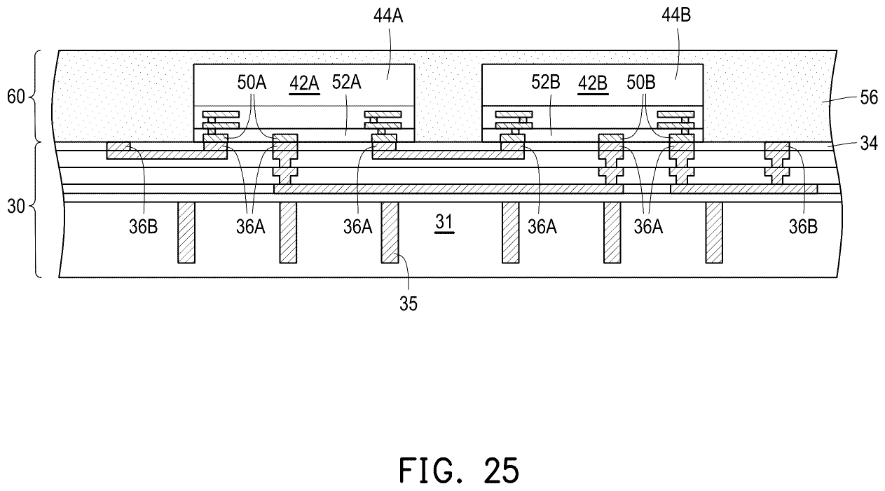

FIG. 24 to FIG. 29 illustrate cross-sectional views of intermediate stages in the manufacturing of a semiconductor package according to some embodiments of the present disclosure. The semiconductor devices 21, 22a in the semiconductor package PKG as shown in FIG. 18 can be in any suitable form. In one embodiment, the semiconductor package PKG may include a System on Integrate Chip (SoIC) package in accordance with some embodiments. FIG. 24 to FIG. 25 illustrate one of the possible process of forming the first semiconductor device 21 in a SoIC package. Some variations of some embodiments are discussed. Throughout the various views and illustrative embodiments, like reference numbers are used to designate like elements.

FIG. 24 illustrates the cross-sectional view in the formation of a wafer 30. In accordance with some embodiments of the present disclosure, the wafer 30 is an interposer wafer, which is free from any active devices such as transistors and/or diodes therein. In accordance with some embodiments of the present disclosure, the interposer wafer 30 is also free from passive devices such as capacitors, inductors, resistors, or the like therein. In some embodiments, the interposer wafer 30 may include a plurality of metal lines and vias therein, with some details of one of a plurality of interposer dies 4 illustrated schematically. The interposer dies 4 are alternatively referred to as interposers or chips hereinafter. The interposer dies 4 are used for routing, as will be discussed in subsequent paragraphs.

The wafer 30 may include a substrate 31 and the features over the top surface of the substrate 31. In accordance with some embodiments of the present disclosure, the substrate 31 is a semiconductor substrate. The substrate 31 may be formed of crystalline silicon, crystalline germanium, crystalline silicon germanium, and/or a III-V compound semiconductor such as GaAsP, AlInAs, AlGaAs, GaInAs, GaInP, GaInAsP, or the like. The semiconductor substrate 31 may also be a bulk silicon substrate or a silicon-on-insulator (SOI) substrate. In accordance with some embodiments in which the substrate 31 is a semiconductor substrate, shallow trench isolation (STI) regions (not shown) may be formed in the substrate 31 to isolate the regions in the substrate 31. In accordance with alternative embodiments, STI regions are not formed in the wafer 30 since the wafer 30 does not have active devices, and hence does not need STI regions to isolation active regions from each other. The substrate 31 may also be a dielectric substrate, which may be formed of silicon oxide, for example. In accordance with some embodiments, the wafer 30 may be a device wafer, which includes a plurality of device dies 4 therein. In accordance with some embodiments, the device dies 4 include active circuits, which include active devices such as transistors (not shown) formed at the top surface of the semiconductor substrate 31.

In accordance with some embodiments, a plurality of through vias 35 are formed to extend into the semiconductor substrate 31, wherein the through-vias are used to electrically inter-couple the features on opposite sides of the semiconductor substrate 31. The through vias 35 are also sometimes referred to as through substrate vias or through silicon vias when substrate 31 is a silicon substrate. The through vias 35 may be formed by forming recesses in the substrate 31 by, for example, etching, milling, laser techniques, a combination thereof, and/or the like. A thin dielectric material may be formed in the recesses, such as by using an oxidation technique. A thin barrier layer may be conformally deposited over the front side of the substrate 31 and in the openings, such as by CVD, ALD, PVD, thermal oxidation, a combination thereof, and/or the like. The barrier layer may include a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 31 by, for example, CMP. Thus, the through vias 21 may include a conductive material and a thin barrier layer between the conductive material and the substrate 31. In accordance with alternative embodiments, no through-vias are formed extending into the semiconductor substrate 31.

In accordance with some embodiments, at least one dielectric layer 33 may be formed over the substrate 31. In accordance with some embodiments of the present disclosure, the dielectric layer 33 is an Inter-Layer Dielectric (ILD), which may be formed of silicon oxide, Phospho Silicate Glass (PSG), Boro Silicate Glass (BSG), Boron-Doped Phospho Silicate Glass (BPSG), Fluorine-Doped Silicate Glass (FSG), Tetra Ethyl Ortho Silicate (TEOS), or the like. The dielectric layer 33 may be formed using thermal oxidation, spin coating, Flowable Chemical Vapor Deposition (FCVD), Atomic Layer Deposition (ALD), Chemical Vapor Deposition (CVD), Plasma Enhanced Chemical Vapor Deposition (PECVD), Low Pressure Chemical Vapor Deposition (LPCVD), or the like.

Over the dielectric layer 33 resides interconnect structure 32. Interconnect structure 32 includes metal lines and vias, which are formed in the dielectric layers 32. The dielectric layers 32 are alternatively referred to as Inter-Metal Dielectric (IMD) layers hereinafter. In accordance with some embodiments of the present disclosure, the dielectric layers 32 are formed of low-k dielectric materials having dielectric constants (k-values) lower than 3.8. For example, the k values of the dielectric layers 32 may be lower about 3.0 or lower than about 2.5. The dielectric layers 32 may be formed of Black Diamond (a registered trademark of Applied Materials), a carbon-containing low-k dielectric material, Hydrogen SilsesQuioxane (HSQ), MethylSilsesQuioxane (MSQ), or the like. In accordance with alternative embodiments of the present disclosure, some or all of the dielectric layers 32 are formed of non-low-k dielectric materials such as silicon oxide, silicon carbide (SiC), silicon carbo-nitride (SiCN), silicon oxy-carbo-nitride (SiOCN), or the like. In accordance with some embodiments of the present disclosure, the formation of the dielectric layers 32 includes depositing a porogen-containing dielectric material, and then performing a curing process to drive out the porogen, and hence the remaining dielectric layers 32 is porous. Etch stop layers (not shown), which may be formed of silicon carbide, silicon nitride, or the like, are formed between the dielectric layers 32, and are not shown for simplicity.

A planarization process such as a CMP process may then be performed to remove the excess portions of the conductive material higher than the top surface of the IMD layer, leaving a metal line in the trench. Then, a surface dielectric layer 34 is formed of a non-low-k dielectric material such as silicon oxide. The surface dielectric layer 34 is alternatively referred to as a passivation layer since it has the function of isolating the underlying low-k dielectric layers (if any) from the adverse effect of detrimental chemicals and moisture. The surface dielectric layer 34 may also have a composite structure including more than one layer, which may be formed of silicon oxide, silicon nitride, Undoped Silicate Glass (USG), or the like. Interposer dies 4 may also include metal pads underlying the surface dielectric layer 34, and the metal pads may include aluminum or aluminum copper pads, Post-Passivation Interconnect (PPI), or the like, which are not shown for simplicity.

Then, a plurality of bond pads 36A and 36B, which are also collectively and individually referred to the bond pads 36, are formed in the surface dielectric layer 34. In accordance with some embodiments of the present disclosure, the bond pads 36A and 36B are formed through a single damascene process, and may also include barrier layers and a copper-containing material formed over the barrier layers. In accordance with alternative embodiments of the present disclosure, the bond pads 36A and 36B are formed through a dual damascene process. Some of the bond pads 36A may be electrically coupled to other bond pads 36A and 36B through the metal lines and vias. In accordance with some embodiments of the present disclosure, each of the bond pads 36A and bond pads 36B is electrically connected to at least one (or more) of other bond pads 36A and 36B through metal lines and vias, and none of the bond pads 36A and 36B is electrically disconnected to all other bond pads 36A and 36B.

Next, at least one device die is bonded to the wafer 30. In the present embodiment, a plurality of device dies 42A and 42B are bonded to the wafer 30, as shown in FIG. 24, and the number of the device dies is not limited thereto. In some embodiments, the device dies 42A and 42B may be a single System on a Chip (SoC) die, multiple SoC stacked dies, or the like. One or each of the device dies 42A and 42B may also be a Central Processing Unit (CPU) die, a Micro Control Unit (MCU) die, an input-output (IO) die, a BaseBand (BB) die, or an Application processor (AP) die. The device dies 42A and 42B may be the same type or different types of dies selected from the above-listed types. In one embodiment, one of the device dies 42A and 42B may be a memory die such as Dynamic Random Access Memory (DRAM) dies or Static Random Access Memory (SRAM) dies. The device dies 42A and 42B in combination function as a package.

The device dies 42A and 42B include substrates 44A and 44B, respectively, which may be semiconductor substrates such as silicon substrates. In accordance with some embodiments, the substrates 44A and 44B are also referred to as semiconductor substrates 44A and 44B. In accordance with some embodiments of the present disclosure, the device dies 42A and 42B may be free from through silicon vias (TSVs) therein. Also, the device dies 42A and 42B include interconnect structures 48A and 48B, respectively, for connecting to the active devices and passive devices in the device dies 42A and 42B. The interconnect structures 48A and 48B include metal lines and vias, which are illustrated schematically. In some embodiments, the substrates 44A and 44B may be free from through-vias therein. Accordingly, all external electrical connections of the device dies 42A and 42B are made through the bond pads 50A and 50B.

In some embodiments, the device die 42A includes a plurality of bond pads 50A and dielectric layer 52A at the illustrated bottom surface. The bottom surfaces of bond pads 50A are coplanar with the bottom surface of dielectric layer 52A. Similarly, the device die 42B includes a plurality of bond pads 50B and dielectric layer 52B at the illustrated bottom surface. The bottom surfaces of the bond pads 50B are coplanar with the bottom surface of dielectric layer 52B.

The bonding of the device dies 42A and 42B to wafer 30 may be achieved through hybrid bonding. For example, the bond pads 50A and 50B are bonded to the bond pads 36A through direct metal bonding (i.e., metal-to-metal direct bonding). In accordance with some embodiments of the present disclosure, the metal-to-metal direct bonding is copper-to-copper direct bonding. Furthermore, the dielectric layers 52A and 52B are bonded to the surface dielectric layer 34, for example, with fusion bonds (which may include Si—O—Si bonds) generated.

To achieve the hybrid bonding, the device dies 42A and 42B are first pre-bonded to the surface dielectric layer 34 and the bond pads 36A by lightly pressing the device dies 42A and 42B against the interposer die 4. Although two device dies 42A and 42B are illustrated, the hybrid bonding may be performed at wafer level, and a plurality of device die groups identical to the illustrated die group including device dies 42A and 42B is pre-bonded, and arrange as rows and columns.

After all device dies 42A and 42B are pre-bonded, an anneal process is performed to cause the inter-diffusion of the metals in the bond pads 36A and the corresponding overlying bond pads 50A and 50B. The annealing temperature may be in the range between about 200° and about 400 °C, and may be in the range between about 300° and about 400 °C in accordance with some embodiments. The annealing time is in the range between about 1.5 hours and about 3.0 hours, and may be in the range between about 1.5 hours and about 2.5 hours in accordance with some embodiments. Through the hybrid bonding, the bond pads 50A and 50B are bonded to the corresponding bond pads 36A through direct metal bonding caused by metal inter-diffusion.

The surface dielectric layer 34 is also bonded to dielectric layers 52A and 52B, with bonds formed therebetween. For example, the atoms (such as oxygen atoms) in one of the surface dielectric layer 34 and the dielectric layers 52A/52B form chemical or covalence bonds with the atoms (such as silicon atoms) in the other one of the surface dielectric layers 34 and the dielectric layer 52A/52B. The resulting bonds between the surface dielectric layers 34 and the dielectric layer 52A/52B are dielectric-to-dielectric bonds. The bond pads 50A and 50B may have sizes greater than, equal to, or smaller than, the sizes of the respective bond pads 36A. The gaps 46 are left between neighboring device dies 42A and 42B.

Further referring to FIG. 24, a backside grinding may be performed to thin the device dies 42A and 42B, for example, to a thickness between about 15 μm and about 30 μm. Through the thinning of the device dies 42A and 42B, the aspect ratio of gaps 46 between neighboring device dies 42A and 42B is reduced. Otherwise, the gap-filling may be difficult due to the otherwise high aspect ratio of gaps 46. In accordance with other embodiments in which the aspect ratio of gaps 46 is not too high for gap filling, the backside grinding is skipped.

Then, referring to FIG. 25, in accordance with some embodiments of the present disclosure, an encapsulating material 56 is formed over the wafer 30. The encapsulating material 56 at least laterally encapsulates the device dies 42A and 42B. The encapsulating material 56 includes dielectric material, which may be deposited using a conformal deposition method such as Atomic Layer Deposition (ALD) or Chemical Vapor Deposition (CVD), or a non-conformal deposition method such as High-Density Plasma Chemical Vapor Deposition (HDPCVD), Flowable Chemical Vapor Deposition (CVD), spin-on coating, or the like.

In some embodiments, the encapsulating material 56 may be formed of an inorganic dielectric material. In accordance with some embodiments of the present disclosure, the encapsulating material 56 includes an oxide such as silicon oxide, which may be formed of TEOS, while other dielectric materials such as silicon carbide, silicon oxynitride, silicon oxy-carbo-nitride, or the like may also be used. The encapsulating material 56 fully fills gaps 46 (shown in FIG. 24), and further includes some portions overlapping device dies 42A and 42B. The encapsulating material 56 may be formed of a non-conformal formation method or a conformal formation method.

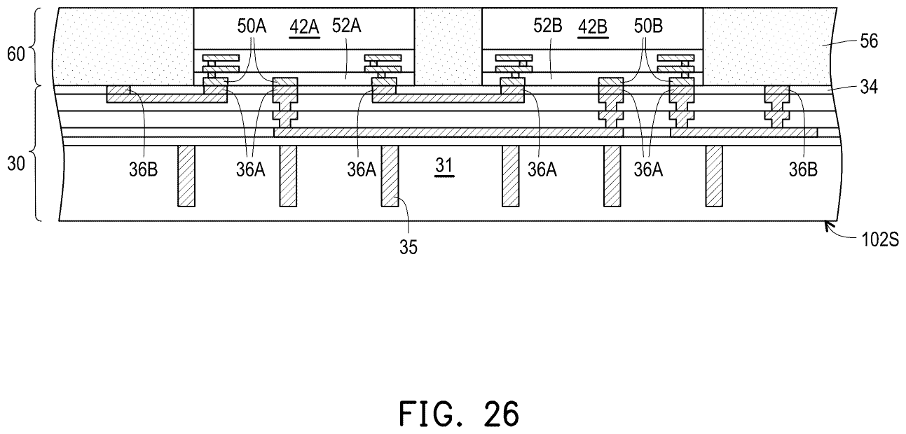

Then, referring to FIG. 26, a planarization process such as a CMP process or a mechanical grinding process is performed to remove the excess portions of the encapsulating material 56. In accordance with some embodiments of the present disclosure, the planarization is stopped when there is a layer of the encapsulating material 56 overlapping the device dies 42A and 42B. As a result, after the planarization process, the substrates 44A of the device die 42A and the substrate 44B of the device die 42B are exposed, and the exposed back surfaces of the device dies 42A and 42B are substantially coplanar with the top surface of the encapsulating material 56. At the time, a reconstructed wafer 60 over the wafer 30 is formed.

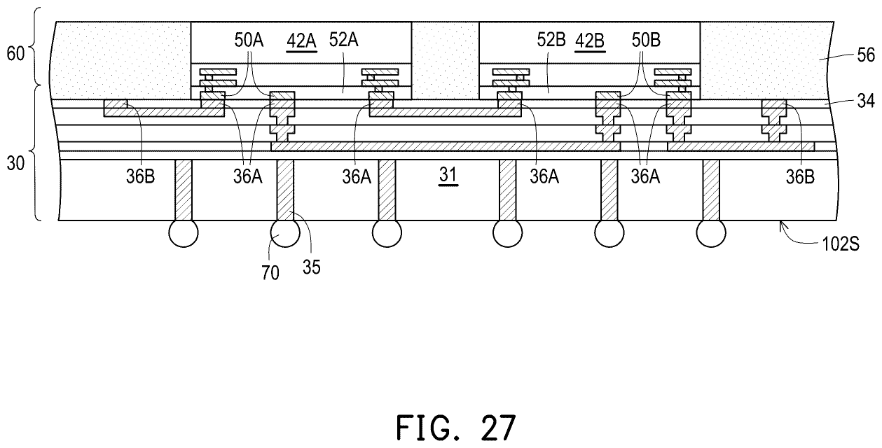

Then, referring to FIG. 26 and FIG. 27, a thinning process is performed on a back side 102S of the substrate 31 to thin the substrate 31 until the through vias 35 are exposed. In detail, the structure of FIG. 26 may be flipped over to prepare for the formation of the back side 102S of the wafer 30. Although not shown, the structure may be placed on a carrier or support structure for the process of FIG. 27. The thinning process may include an etching process, a grinding process, the like, or a combination thereof. In some embodiments, a redistribution structure (not shown) may be formed on the back side 102S of the substrate 31, and is used to electrically connect the through vias 35 together and/or to external devices.

Then, a plurality of conductive connectors 70 are formed over the redistribution structure and are electrically coupled to the through vias 35. In some embodiments, the metallization patterns include UBMs. In the illustrated embodiment, the pads are formed in openings of the dielectric layers of the redistribution structure. In another embodiment, the pads (UBMs) can extend through an opening of a dielectric layer of the redistribution structure and also extend across the top surface of the redistribution structure.

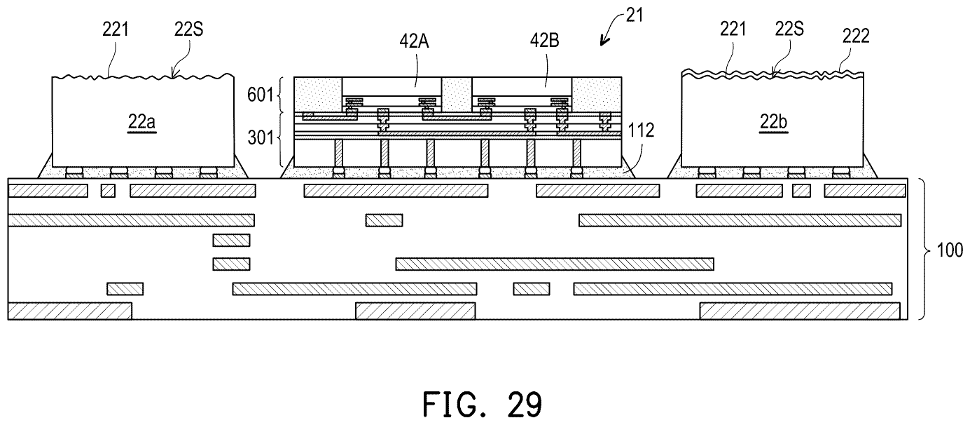

In some embodiments, the conductive connectors 70 are solder balls and/or bumps, such as ball grid array (BGA) balls, C4 micro bumps, ENIG formed bumps, ENEPIG formed bumps, or the like. The conductive connectors 70 may include a conductive material such as solder, copper, aluminum, gold, nickel, silver, palladium, tin, the like, or a combination thereof. In some embodiments, the conductive connectors 70 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 70 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the conductive connectors 70. The metal cap layer may include nickel, tin, tin-lead, gold, silver, palladium, indium, nickel-palladium-gold, nickel-gold, the like, or a combination thereof and may be formed by a plating process. The conductive connectors 70 may be used to bond to an additional electrical component, which may be a semiconductor substrate, a package substrate, a Printed Circuit Board (PCB), or the like (see the interposer 100 in FIG. 29).

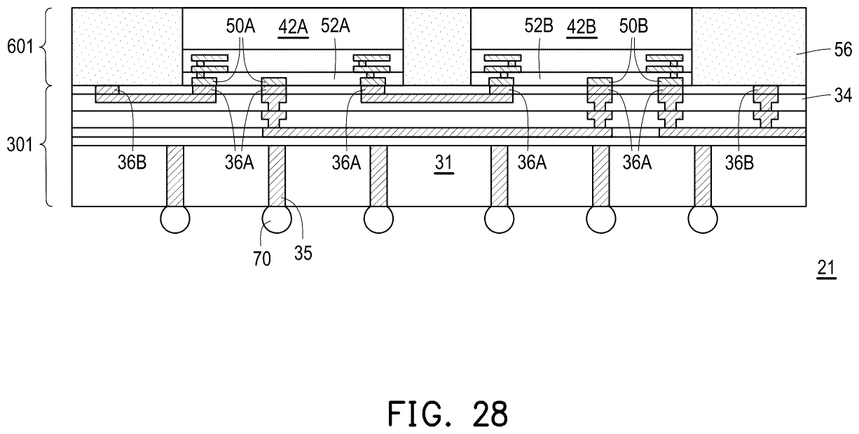

In the embodiment, the structure shown in FIG. 27 is referred to as a composite wafer, which includes a reconstructed wafer 60 bonded over the wafer 30. Then, referring to FIG. 28, a singulation (die-saw) process is performed on composite wafer shown in FIG. 27 to separate the composite wafer into a plurality of (first) semiconductor devices 21. One of the (first) semiconductor devices 21 is illustrated in FIG. 28. In the present embodiments, the (first) semiconductor device 21 is a die stack structure, which includes a lower die 301, and an upper die 601 stacked over and bonded to the lower die 301. The singulation process may include sawing, dicing, or the like. To be more specific, the singulation process is performed on the encapsulating material 56 and the wafer 30 to separate the composite wafer into a plurality of die stack structures 21. After the singulation process, the lower die 301 is singulated from the interposer wafer 30 to be functioned as an interposer, and the upper die 601 including the device die 42A and 42B encapsulated by the encapsulating material 56 is bonded to the interposer 301 through hybrid bonding. In other embodiment, the upper die 601 and the lower die 301 may both be device dies and directly bonded to the each other through hybrid bonding. The disclosure is not limited thereto.

Then, referring to FIG. 29, the first semiconductor devices 21 shown in FIG. 28 are bonded to the interposer structure 100. The conductive connectors 70 may be reflowed to create a bond between the interposer structure 100 and the first semiconductor devices 21. In some embodiments, a plurality of second semiconductor devices 22a and/or 22b are also bonded to the interposer structure 100 and arranged around the first semiconductor devices 21.

In the previous embodiments, the surface treatment process (including the patterning process for forming the grooves 221 and/or the adhesion promoting process for forming the adhesion promoting layer 222) is performed after the step illustrated in FIG. 8 (i.e., after the package structure SM is bonded to the substrate 300). In other embodiments, the surface treatment process may be performed before the step illustrated in FIG. 8 (i.e., before the package structure SM is provided over the substrate 300). In the current embodiment, the surface treatment process is performed on the backside surface 22S of the second semiconductor devices 22a and/or 22b before the second semiconductor devices 22a and/or 22b are bonded to the interposer structure 100. That is, the second semiconductor devices 22a and/or 22b are bonded to the interposer structure 100 with the grooves 221 already formed on the backside surfaces 22S and/or with the adhesion promoting layer 222 already covering at least one of the backside surfaces 22S. The disclosure is not limited there to. Then, as illustrated in FIG. 18, the thermal interface material 23 may be applied to the backside surfaces of the first semiconductor devices 21 and the backside surfaces 22S of the second semiconductor devices 22a and/or 22b, and the lid structure 500 is provided over the substrate 300 and attached to the semiconductor devices 21, 22a and/or 22b through the thermal interface material 23.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a substrate, a center die over the substrate, a plurality of peripheral dies over the substrate and surrounding the center die, a thermal interface material and a lid structure. The plurality of peripheral dies include a patterned peripheral die having a groove pattern on a backside surface of the patterned peripheral die. The thermal interface material is disposed on the center die and the plurality of peripheral dies and filling the groove pattern. The lid structure is disposed over the substrate and attached to the center die and the plurality of peripheral dies through the thermal interface material. In one embodiment, the semiconductor package further includes an interposer structure over the substrate, wherein the center die and the plurality of peripheral dies are disposed over the interposer structure in a side by side manner. In one embodiment, the groove pattern includes a plurality of grooves arranged in honeycomb pattern, grid, or triangle array. In one embodiment, the patterned peripheral die further includes an adhesion promoting layer covering the backside surface of the patterned peripheral die and covering the groove pattern in a conformal manner. In one embodiment, the adhesion promoting layer includes nitrogen, carbon, oxygen, sulfur, phosphorus, chlorine, or fluorine. In one embodiment, the patterned peripheral die includes a first patterned peripheral die having an adhesion promoting layer covering a backside surface of the first patterned peripheral die in a conformal manner and a second patterned peripheral die free of the adhesion promoting layer. In one embodiment, a ratio of a surface area of a backside surface of the first patterned peripheral die to a surface area of backside surfaces of the center die and the plurality of peripheral dies is substantially equal to or greater than 20% and substantially equal to or smaller than 50%. In one embodiment, a ratio of a surface area of a backside surface of the second patterned peripheral die to a surface area of backside surfaces of the center die and the plurality of peripheral dies is substantially equal to or greater than 5% and substantially equal to or smaller than 20%. In one embodiment, a minimum thickness of the thermal interface material is greater than a depth of the groove pattern.

In accordance with some embodiments of the disclosure, a semiconductor package includes a substrate, a package structure, a thermal interface material, and a lid structure. The package structure is disposed over the substrate and includes a first semiconductor device and a plurality of second semiconductor devices over an interposer structure, wherein the plurality of second semiconductor devices surround the first semiconductor device, and a first step height between a highest point and a lowest point of a backside surface of the first semiconductor device is smaller than a second step height between a highest point and a lowest point of one of backside surfaces of the plurality of second semiconductor devices. The thermal interface material is disposed on the backside surface of the first semiconductor device and the backside surfaces of the plurality of second semiconductor devices. The lid structure is disposed over the substrate and thermally coupled to the first semiconductor device and the plurality of second semiconductor devices through the thermal interface material. In one embodiment, the interposer structure is mounted on the substrate through a plurality of conductive terminals. In one embodiment, a thickness of the thermal interface material is denoted as H, and the average surface roughness of the backside surfaces of the plurality of second semiconductor devices is substantially equal to or greater than H/10, and substantially smaller than H/2. In one embodiment, the plurality of second semiconductor devices includes a corner die having an adhesion promoting layer covering a backside surface of the corner die in a conformal manner. In one embodiment, a corner step height of the backside surface of the corner die is greater than the second step height of the one of the backside surfaces of the plurality of second semiconductor devices.

In accordance with some embodiments of the disclosure, a method of manufacturing a semiconductor package includes: providing a package structure over the substrate, wherein the package structure includes a first semiconductor device and a plurality of second semiconductor devices surrounding the first semiconductor device; performing a surface treatment process over a backside surface of one of the plurality of second semiconductor devices to form a processed backside surface, so that the one of the plurality of second semiconductor devices has a groove pattern on the backside surface of the one of the plurality of second semiconductor devices; providing a thermal interface material over the first semiconductor device and the plurality of second semiconductor devices; and providing a lid structure over the substrate, wherein the lid structure covers the package structure and is thermally coupled to the first semiconductor device and the plurality of second semiconductor devices through the thermal interface material. In one embodiment, the surface treatment process includes performing a patterning process to form a plurality of grooves over the backside surface of the one of the plurality of second semiconductor devices. In one embodiment, the surface treatment process includes: performing a patterning process to form a groove pattern over backside surfaces of the plurality of second semiconductor devices; and performing an adhesion promoting process over at least one of the plurality of second semiconductor devices. In one embodiment, the adhesion promoting process includes spin coating an adhesion promoting layer to cover the backside surface of the at least one of the plurality of second semiconductor devices in a conformal manner. In one embodiment, the adhesion promoting process includes performing a plasma treatment over a backside of the at least one of the plurality of second semiconductor devices. In one embodiment, the surface treatment process is performed before the package structure is provided over the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate;
a first die over the substrate;
a plurality of peripheral dies over the substrate and surrounding the first die, wherein the plurality of peripheral dies comprise a patterned peripheral die having a groove pattern on a backside surface of the patterned peripheral die;
a thermal interface material disposed on the first die and the plurality of peripheral dies and filling the groove pattern; and
a lid structure disposed over the substrate and attached to the first die and the plurality of peripheral dies through the thermal interface material.

2. The semiconductor package as claimed in claim 1, further comprising an interposer structure over the substrate, wherein the first die and the plurality of peripheral dies are disposed over the interposer structure in a side by side manner.

3. The semiconductor package as claimed in claim 1, wherein the groove pattern comprises a plurality of grooves arranged in honeycomb pattern, grid, or triangle array.

4. The semiconductor package as claimed in claim 1, wherein the patterned peripheral die further comprises an adhesion promoting layer covering the backside surface of the patterned peripheral die and covering the groove pattern in a conformal manner.

5. The semiconductor package as claimed in claim 4, wherein the adhesion promoting layer comprises nitrogen, carbon, oxygen, sulfur, phosphorus, chlorine, or fluorine.

6. The semiconductor package as claimed in claim 1, wherein the patterned peripheral die comprises a first patterned peripheral die having an adhesion promoting layer covering a backside surface of the first patterned peripheral die in a conformal manner and a second patterned peripheral die free of the adhesion promoting layer.

7. The semiconductor package as claimed in claim 6, wherein a ratio of a surface area of a backside surface of the first patterned peripheral die to a surface area of backside surfaces of the first die and the plurality of peripheral dies is substantially equal to or greater than 20% and substantially equal to or smaller than 50%.

8. The semiconductor package as claimed in claim 6, wherein a ratio of a surface area of a backside surface of the second patterned peripheral die to a surface area of backside surfaces of the first die and the plurality of peripheral dies is substantially equal to or greater than 5% and substantially equal to or smaller than 20%.

9. The semiconductor package as claimed in claim 1, wherein a minimum thickness of the thermal interface material is greater than a depth of the groove pattern.

10. A semiconductor package, comprising:
a substrate;
a package structure disposed over the substrate and comprising a first semiconductor device and a plurality of second semiconductor devices over an interposer structure, wherein the plurality of second semiconductor devices surround the first semiconductor device, and a first step height between a highest point and a lowest point of a backside surface of the first semiconductor device is smaller than a second step height between a highest point and a lowest point of one of backside surfaces of the plurality of second semiconductor devices;
a thermal interface material disposed on the backside surface of the first semiconductor device and the backside surfaces of the plurality of second semiconductor devices; and
a lid structure disposed over the substrate and thermally coupled to the first semiconductor device and the plurality of second semiconductor devices through the thermal interface material.

11. The semiconductor package as claimed in claim 10, wherein the interposer structure is mounted on the substrate through a plurality of conductive terminals.

12. The semiconductor package as claimed in claim 10, wherein a thickness of the thermal interface material is denoted as H, and an average surface roughness of the backside surfaces of the plurality of second semiconductor devices is substantially equal to or greater than H/10, and substantially smaller than H/2.

13. The semiconductor package as claimed in claim 10, wherein the plurality of second semiconductor devices comprises a corner die having an adhesion promoting layer covering a backside surface of the corner die in a conformal manner.

14. The semiconductor package as claimed in claim 13, wherein a corner step height of the backside surface of the corner die is greater than the second step height of the one of the backside surfaces of the plurality of second semiconductor devices.

15. A method of manufacturing a semiconductor package, comprising:
providing a package structure over the substrate, wherein the package structure comprises a first semiconductor device and a plurality of second semiconductor devices surrounding the first semiconductor device;
performing a surface treatment process over a backside surface of one of the plurality of second semiconductor devices to form a processed backside surface, so that the one of the plurality of second semiconductor devices has a groove pattern on the backside surface of the one of the plurality of second semiconductor devices;
providing a thermal interface material over the first semiconductor device and the plurality of second semiconductor devices; and
providing a lid structure over the substrate, wherein the lid structure covers the package structure and is thermally coupled to the first semiconductor device and the plurality of second semiconductor devices through the thermal interface material.

16. The method of manufacturing the semiconductor package as claimed in claim 15, wherein the surface treatment process comprises performing a patterning process to form a plurality of grooves over the backside surface of the one of the plurality of second semiconductor devices.

17. The method of manufacturing the semiconductor package as claimed in claim 15, wherein the surface treatment process comprises:
performing a patterning process to form a groove pattern over backside surfaces of the plurality of second semiconductor devices; and
performing an adhesion promoting process over at least one of the plurality of second semiconductor devices.

18. The method of manufacturing the semiconductor package as claimed in claim 17, wherein the adhesion promoting process comprises spin coating an adhesion promoting layer to cover the backside surface of the at least one of the plurality of second semiconductor devices in a conformal manner.

19. The method of manufacturing the semiconductor package as claimed in claim 17, wherein the adhesion promoting process comprises performing a plasma treatment over a backside of the at least one of the plurality of second semiconductor devices.

20. The method of manufacturing the semiconductor package as claimed in claim 15, wherein the surface treatment process is performed before the package structure is provided over the substrate.
